(19) United States
(12) Patent Application Publication
(10) Pub. No.: US 2006/0117241 A1
(43) Pub. Date: Jun. 1, 2006

(54) Method and apparatus for managing disc defects

(76) Inventors: Jung-wan Ko, Suwon-si (KR); Kyung-Geun Lee, Seongnam-si (KR)

Correspondence Address: STEIN, MCEWEN & BUI, LLP, 1400 EYE STREET, NW, SUITE 300, WASHINGTON, DC, 20005, US

(21) Appl. No.: 10/527,089

(22) PCT Filed: Sep. 9, 2003
(86) PCT No.: PCT/KR03/01878

§ 371 Date: Aug. 30, 2005

(30) Foreign Application Priority Data
Sep. 10, 2002 (KR) 10-2002-054755

(51) Int. Cl. G11C 29/00

(52) U.S. Cl. 714/763

(57) ABSTRACT

A defect management method and apparatus including (a) recording data in predetermined units of data; (b) verifying the recorded data to detect an area of the disc in which a defect exists; (c) designating an area from the defective area to the following area containing data as the defective area or designating only the defective area as the defective area; (d) recording information regarding the designated defective area as temporary defect information in a data area of the disc; and (e) recording information, which is used to manage the temporary defect information, in a temporary defect management information area. The method and apparatus are applicable to write once discs and suitable for recording different types of data, thereby enabling more appropriate real-time data reproduction.

### CROSS-REFERENCE TO RELATED APPLICATIONS

This application claims the benefit of International Application No. PCT/KR2003/001878, filed on Sep. 9, 2003 which is based on Korean Application No. 2002-54755, filed Sep. 10, 2002 in the Korean Intellectual Property Office, the disclosures of which are incorporated herein by reference.

### BACKGROUND OF THE INVENTION

1. Field of the Invention

The present invention relates to disc defect management, and, more particularly, to a method of managing a defect in a disc in a manner regarding different types of data and an apparatus to manage a defect in a disc.

2. Description of the Related Art

Defect management refers to a process of rewriting the data stored in a user data area of a disc in which a defect exists. The data is rewritten to the data area of the disc to compensate the data loss caused by the defect. In general, defect management is performed using linear replacement or slipping replacement. In linear replacement, the user data area in which a defect exists is replaced with a spare data area having no defects. In slipping replacement, the user data area with the defect is slipped and the next user data area having no defects is used.

Both linear replacement and slipping replacement are applicable only to discs, such as a DVD-RAM/RW, on which data is repeatedly recorded and recording is performed using a random access method. In other words, linear replacement and slipping replacement are difficult to apply to write once discs on which recording is allowed only once. In general, the presence of defects in a disc is detected by recording data on the disc and confirming whether or not data has been recorded correctly on the disc. However, once data is recorded on a write once disc, overwriting new data and managing defects therein is impossible.

After the development of CD-R and DVD-R, a high-density write once disc with a recording capacity of several dozen GBs was introduced. This type of disc may be used as a backup disc, since this type of disc is not expensive and allows random access so as to enable fast reading operations. However, defect management is not available for write once discs. Therefore, a backup operation is discontinued when a defective area, i.e., an area where a defect exists, is detected during the backup operation because defect management on a write once disc is not performed. In general, a backup operation is performed when a system is not frequently used, e.g., at night when a system manager does not operate the system.

However, the recording of user data that is recorded from a defective area of the data area to the data area so as to enable defect management is not always a satisfactory solution. For real-time reproduction of data, appropriately reading data on time is important. In general, audio/video (AV) data requires reproduction in real time since the reproduction of AV data is perceived by the visual and auditory senses of a human being during the reproduction. Human visual and auditory senses are more sensitive to an error in real-time reproduction of AV data than an error in reproduction of specific AV data content caused by a trivial defect contained in the AV data. In fact, human ears may be incapable of detecting an error when audio data is incompletely reproduced. As specified previously, when an area of a disc is designated as a defective area, slipping replacement may be used to rewrite data to a following area. That is, when an area of a disc is designated as a defective area, the following area where data is recorded is also considered to be unavailable and is determined to be a defective area, and the data recorded in the defective area is rewritten. In this case, the defective area is skipped and data is read from the next area during reproduction of the data. However, skipping the defective area causes a delay in reading data from the disc, and the delay in reading makes reproduction of the data in real-time difficult. As is described above, human ears are more sensitive to an error caused by a failure of real-time reproduction than an error caused by incomplete reproduction of AV data. Unlike AV data, reproducing, editing, or searching for control data may be relatively very difficult when even a small amount of the control data is lost.

### SUMMARY OF THE INVENTION

The present invention provides a defect management method and apparatus that manage a defect occurring in a disc in a manner suitable to record different types of data so as to improve reproduction characteristics.

The present invention also provides a defect management method and apparatus that are applicable to a write once disc and manage a defect occurring in that disc in a manner suitable to record different types of data, thereby improving reproduction characteristics.

According to an aspect of the present invention, there is provided a method of managing defects in a disc, comprising: (a) recording data in predetermined units of data; (b) verifying the recorded data to detect an area of the disc in which a defect exists; (c) designating an area from the defective area to the following area containing data as a defective area or designating only the defective area as the defective area; (d) recording information regarding the designated defective area as temporary defect information in a data area of the disc; and (e) recording information, which is used to manage the temporary defect information, in a temporary defect management information area.

According to an aspect of the invention, the method further includes (f) repeating operations (a) through (e) before finalizing of the disc, wherein previously recorded information is recorded with the temporary defect information during the (d) operation; and (g) recording information, which is most recently recorded in the temporary defect information area and the temporary defect management information area in a defect management area during the finalizing of the disc.

According to an aspect of the invention, during the (c) operation, the area from the defective area to the following area containing data is designated as the defective area, or only the defective area is designated as the defective area, depending on the type of the recorded data. Also, according to a further aspect of the invention, during the (c) operation, only the defective area is designated as the defective area when the recorded data is AV data, and the area from the defective area to the following area containing data is designated as the defective area when the recorded data is control data.

According to another aspect of the present invention, there is provided a method of managing defects in a disc, comprising: (a) recording data in predetermined units of data; (b) verifying the recorded data to detect an area of the disc in which a defect exists; (c) designating an area from the defective area to the following area containing data as a defective area, or designating only the defective area as the defective area; (d) storing information regarding the designated defective area as first temporary defect information in memory; (e) repeating operations (a) through (d) before a recording operation is expected to end; (f) reading the temporary defect information from the memory and recording the temporary defect information in a temporary defect information area of the data area so as to correspond to the recording operation, when the recording operation is expected to end; and (g) recording information, which is used to manage the information recorded in the temporary defect information area in the (f) operation, in a temporary defect management information area.

According to an aspect of the invention, during the (f) operation, information to designate the temporary defect information area is further recorded in the temporary defect information area.

According to an aspect of the invention, the method further includes (h) repeating operations (a) through (f) before finalizing of the disc, wherein previously recorded information is recorded with the temporary defect information during the (f) operation in the temporary defect information area; and (i) recording information, which is most recently recorded in the temporary defect information area and the temporary defect management information area, in a defect management area.

According to an aspect of the invention, during the (c) operation, the area from the defective area to the following area containing data is designated as the defective area, or only the defective area is designated as the defective area, depending on the type of the recorded data. According to a further aspect of the invention, during the (c) operation, only the area having the defect is designated as the defective area when the recorded data is AV data, and the area from the defective area to the following area containing data is designated as the defective area when the recorded data is control data.

According to yet another aspect of the present invention, there is provided a recording apparatus comprising a recording/reading unit that records data on or reads data from a disc; and a controller that verifies the data recorded on the disc using the recording/reading unit so as to detect an area of the disc in which a defect exists, designates an area from the defective area to the following area containing data as a defective area or designates only the defective area as the defective area, creates information regarding the designated defective area, provides the created information to the recording/reading unit, controls the recording/reading unit to record the created information as temporary defect information in a data area of the disc, creates management information to manage the temporary defect information, provides the management information to the recording/reading unit, and controls the recording/reading unit to record the management information in a temporary defect management area.

According to an aspect of the invention, the controller controls the recording/reading unit to further record the previously recorded information with the information, and controls the recording/reading unit to record information, which is most recently recorded in the temporary defect information area and the temporary defect management information area in a defect management area during finalizing of the disc. According to another aspect of the invention, the controller designates the area from the defective area to the following area containing data as the defective area, or designates only the defective area as the defective area, depending on the type of the recorded data. According to a further aspect of the invention, the controller designates only the defective area as the defective area when the recorded data is AV data, and designates the area from the area to the following area containing data as the defective area when the recorded data is control data.

According to still another aspect of the present invention, there is provided a recording apparatus comprising memory; a recording/reading unit that records data on a disc in predetermined units of data and reads the recorded data from the disc; and a controller that verifies the data recorded on the disc using the recording/reading unit so as to defect an area of the disc in which a defect exists; designates the area from the defective area to the following area containing data as the defective area or designates only the defefctive area as the defective area; stores information regarding the designated defective area as first temporary defect information in the memory; repeats the verifying of the data, the designating of the defective area, and the storing of information regarding the designated defective area before a recording operation is expected to end; reads the temporary defect information from the memory when the recording operation is expected to end; provides the read temporary defect information to the recording/reading unit; controls the recording/reading unit to record the temporary defect information in a temporary defect information area of the data area in a manner corresponding to the recording operation; creates management information to manage the temporary defect information area; provides the management information to the recording/reading unit; and controls the recording/reading unit to record the management information in a temporary defect management information area.

According to an aspect of the invention, the controller creates information for the temporary defect information area, provides the created information to the recording/reading unit, and controls the recording/reading unit to further record the created information in the temporary defect information area. According to another aspect of the invention, the controller controls the recording/reading unit to further record the previously recorded information with the information; reads information, which is most recently recorded in the temporary defect information area and the temporary defect management information area, during the finalizing of the disc; and controls the recording/reading unit to record the most recently recorded information in the defect management area again. According to yet another aspect of the invention, the controller designates the area from the defective area to the following area containing data as the defective area or designates only the defective area as the defective area, depending on the type of the recorded data. According to a further aspect of the invention, the controller designates only the defective area as the defective area when the recorded data is AV data, and designates the area from the defective area to the following area containing data as the defective area when the recorded data is control data.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a recording apparatus according to a preferred embodiment of the present invention;

FIG. 2A illustrates a structure of a single record layer disc according to a preferred embodiment of the present invention;

FIG. 2B illustrates a structure of a double record layer disc according to a preferred embodiment of the present invention;

FIG. 3 illustrates details of the structures of the discs shown in FIGS. 2A and 2B;

FIG. 4 is a diagram illustrating a process in which temporary defect information is created and recorded, according to a preferred embodiment of the present invention;

FIG. 5 illustrates data structures of temporary defect information according to a preferred embodiment of the present invention;

FIG. 6 illustrates data structures of information regarding defect #i and information regarding temporary defect information #i, which are recorded in a temporary defect information area;

FIG. 7 is a flowchart illustrating a defect management method according to a preferred embodiment of the present invention; and

FIG. 8 is a flowchart illustrating a defect management method according to another preferred embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

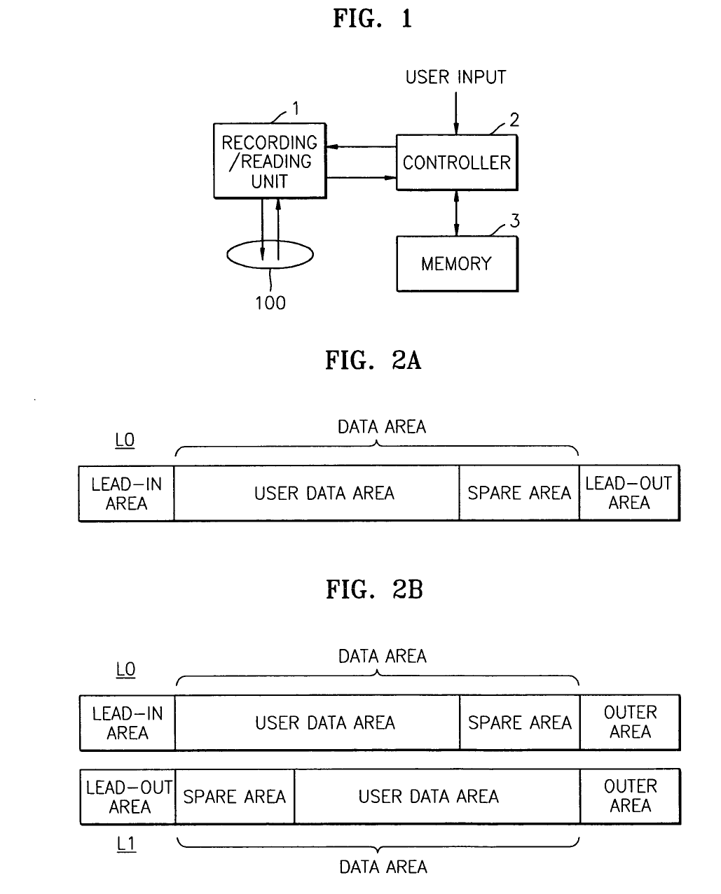

FIG. 1 is a block diagram of a recording apparatus according to an embodiment of the present invention. Referring to FIG. 1, the recording apparatus includes a recording/reading unit 1, a controller 2, and a memory 3. The recording/reading unit 1 records data on a disc 100 (e.g., an information storage medium according to an embodiment of the present invention), and reads back the data from the disc 100 to verify the accuracy of the recorded data. The controller 2 performs defect management according to the present invention. In this embodiment, the controller 2 uses a verify-after-write method in which the accuracy of data is verified after the data is recorded in predetermined units. More specifically, the controller 2 causes the recording/reading unit 1 to record user data on the disc 100 in predetermined units, and verifies the accuracy of the user data so as to detect defects in the user data.

If a defect is detected, the controller 2 creates defect information that indicates the position of a defective area on the disc 100. If an area containing a defect is detected, the controller 2 designates only the specific area as a defective area, designates a set of areas from the specific area to the following area containing data, and/or completes a combination of the designation of only the specific area as a defective area and the designation of a set of areas from the specific area to the following area containing data. Every time defect information is created, the controller 2 stores the defect information in the memory 3. When the amount of stored defect information reaches a predetermined level, the stored defect information is recorded as temporary defect information on the disc 100. Also, the controller 2 records management information, which is used to manage the recorded temporary defect information, as temporary defect management information on the disc 100.

In this embodiment, recording temporary defect information and temporary defect management information on the disc 100 is periodically performed per recording operation. A recording operation is a unit of work that is determined according to either an intention of a user or is a recording work to be performed. According to this embodiment of the invention, a recording operation indicates a process in which the disc 100 is loaded into the recording apparatus, data is recorded on the disc 100, and the disc 100 is taken out from the recording apparatus. During the recording operation, data is recorded and verified at least once; in general, though, data is actually verified several times. When a user presses the eject button (not shown) of the recording apparatus in order to remove the disc 100 after the recording of data, the controller 2 expects the recording operation to be terminated. Next, the controller 2 creates temporary defect information and temporary defect management information, and provides the created temporary defect information and the created temporary defect management information to the recording/reading unit 1 to be recorded on the disc 100. The temporary defect information, which is obtained as a result of the recording and verifying by the controller 2, is stored in the memory 3.

If the recording of data on the disc 100 is completed, i.e., no more data will be recorded on the disc 100 (i.e., the disc 100 is to be finalized), the controller 2 records the temporary defect information and the temporary defect management information in a defect management area (DMA) of the disc 100.

FIGS. 2A and 2B illustrate structures of a disc according to an embodiment of the present invention. FIG. 2A illustrates, in detail, a representation of a single recording layer of disc 100 having a recording layer L0′. The disc 100 includes a lead-in area, a data area, and a lead-out area as shown. The lead-in area is located in an inner part of the disc 100 in a radial direction and the lead-out area is located in an outer part of the disc 100 in a radial direction. The data area is located between the lead-in area and the lead-out area, and is divided into a user data area and a spare area. The user data area is an area where user data is recorded. The spare area is the substitute area for a user data area having a defect, serving to compensate for loss in the recording area due to a defect. On the assumption that defects may occur within the disc 100, in an embodiment of the invention, the spare area assumes 5% of the entire data capacity of the disc 100, so that a greater amount of data may be recorded on the disc 100. Also, in an embodiment of the invention, the spare area is provided at an end of the data area of the disc 100. In the case of a write once disc, the spare area must be located at the end of the data area of the disc. This allows slipping replacement to be performed while the spare area data is recorded, starting from the inner part toward the outer part of the disc 100.

According to this embodiment, the spare area is present only between the user data area and the lead-out area. If necessary, a portion of the user data area may be used as another spare area, that is, more than one spare area may be present between the user data area and the lead-out area.

FIG. 2B illustrates a representation of a double recording layer of disc 100 having two recording layers L0 and L1. A lead-in area, a data area, and an outer area are sequentially formed from an inner part of the first recording layer L0 in a radial direction to an outer part thereof. Also, an outer area, a data area, and a lead-out area are sequentially formed from an outer part of the second recording layer L1 in a radial direction to an inner part thereof. Unlike the single recording layer L0′ shown in FIG. 2A, the lead-out area is present in the inner part of the disc 100 of FIG. 2B. That is, the disc 100 of FIG. 2B has an opposite track path (OTP) in which data is recorded starting from the lead-in area of the first recording layer L0 toward the outer area and continuing from the outer area of the second recording layer L1 to the lead-out area.

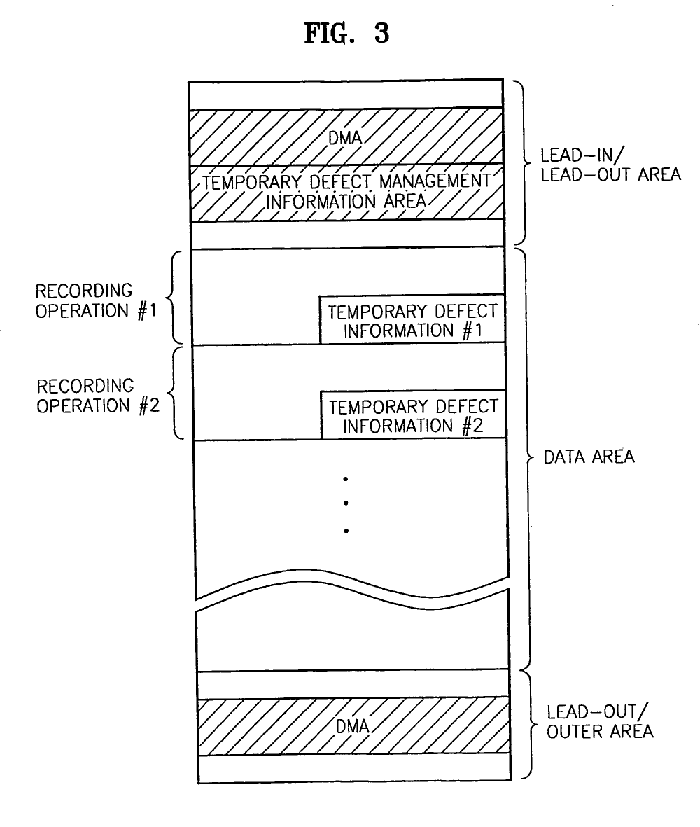

FIG. 3 illustrates details of the structures of the embodiments of the disc 100 shown in FIGS. 2A and 2B. Referring to FIG. 3, a disc management area (DMA) is present at least once in the lead-in area, the lead-out area, or the outer area of the disc 100. Also, a temporary defect management area is formed at least once in the lead-in area or the lead-out area. A temporary defect information area is formed in the data area according to a recording operation.

In general, information which relates to managing defects in the disc 100 is recorded in the DMA. Such information includes the structure of the disc 100 that allows the disc 100 to manage defects, the position of defect information, whether defect management is performed or not, and the position and size of a spare area. In the case of a write once disc, new data is recorded after previously recorded data when the previously recorded data changes. In general, when a disc is loaded into a recording/reproducing apparatus, the apparatus reads data from a lead-in area and a lead-out area of the disc to determine how to manage the disc, and records data on or reads data from the disc. However, if the amount of data recorded in the lead-in area increases, a longer time is spent on preparing the recording or reproducing of data after loading the disc. Accordingly, the present invention proposes the use of temporary defect management information and temporary defect information. That is, only the temporary defect management information, which is comparatively more important than the temporary defect information, is recorded in the lead-in area. The temporary defect information is recorded in the data area. In an embodiment of the invention, new information is added to the previously recorded information in the temporary defect information area so that all recorded information is accumulated therein. The recording/reproducing apparatus reads the most recently recorded temporary defect information. The recording/reproducing apparatus then detects defects throughout the disc based on the result of the reading of the most recently recorded temporary defect information. Thus, information regarding the location of the most recently recorded temporary defect information is recorded in the temporary defect management information area where the temporary defect management information is recorded.

More specifically, information regarding a defect that occurred in a recording unit #1 and information regarding a defect that occurred in a recording unit #2 are recorded in a temporary defect information area #1 and a temporary defect information area #2, respectively. Defect management information to manage the temporary defect information areas #1, #2, . . . and #n is recorded in the temporary defect management information area. If additional data cannot be recorded on the disc 100 or a user does not wish to record any more data on the disc 100, i.e., the disc 100 needs to be finalized. In a finalization operation of the disc 100, the temporary defect information recorded in the temporary defect information area and the temporary defect management information recorded in the temporary defect management information area are all recorded in the DMA.

The reason to record the temporary defect management information and the temporary defect information in the DMA again will now be explained. Where additional data will not be recorded on the disc 100, i.e., the disc 100 needs to be finalized, the temporary defect management information, which is updated several times, and the temporary defect information, which is recorded in the data area, are rewritten to the DMA of the lead-in area so as to enable the relatively fast reading of information recorded on the disc 100. Also, increasing the reliability of information by recording the defect management information in a plurality of areas is possible.

In this embodiment, defect information recorded in the temporary defect information areas #0 through #i-1 is recorded repeatedly in a temporary defect information area #i. Therefore, reading the defect information from the last temporary defect information area and recording this information in the DMA again during the finalizing of the disc 100 is sufficient.

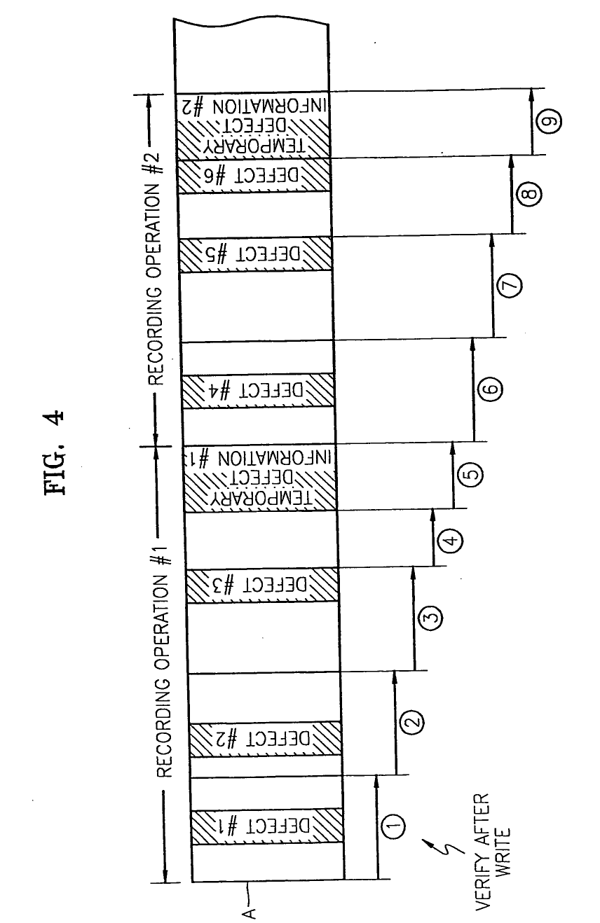

FIG. 4 is a diagram illustrating a process in which temporary defect information is created and recorded. With reference to FIG. 4, a unit of data may be processed in units of sectors or clusters. A sector denotes a minimum unit of data that is managed in a file system of a computer or in an application, and a cluster denotes a minimum unit of data that may be physically recorded on a disc at once. In general, one or more sectors constitute a cluster.

There are two types of sectors: a physical sector and a logical sector. The physical sector is an area on a disc where a sector of data is to be recorded. An address to detect the physical sector is called a physical sector number (PSN). The logical sector is a unit to manage data in a file system or in an application. An address to detect the logical sector is called a logical sector number (LSN). A disc recording/reproducing apparatus detects the recording position of data using a PSN and, when recording data on a disc, substantially all of the data is managed in units of LSNs in a computer or in an application. The relationship between an LSN and a PSN is changed by a controller of the recording/reproducing apparatus, based on whether the disc contains a defect and an initial position of recording data.

Referring to FIG. 4, A denotes a data area in which PSNs are allocated to a plurality of sectors (not shown) in ascending order. In general, each LSN corresponds to at least one PSN. However, since LSNs are allocated to non-defective sectors in ascending order, the correspondence between the PSNs and the LSNs is not maintained when a disc has a defective area, even if the size of a physical sector is the same as that of a logical sector.

Sections \textcircled{1} through \textcircled{5} denote units of data in which verifying work is performed after recording work. In detail, a recording apparatus records user data in section \textcircled{1}, returns to the start of section \textcircled{1}, and checks if the user data is appropriately recorded or if a defect exists in section \textcircled{1}. If a defect is detected, only the area covering the defect in section \textcircled{1} is designated as a defective area. Here, the defect is designated as defect #1. Next, the recording apparatus records the user data in section \textcircled{2}, returns to the start of section \textcircled{2}, and checks if the user data is appropriately recorded or if a defect exists in the start. If a defect is detected, only the area covering the defect in section \textcircled{2} is designated as a defective area and the defect is designated as defect #2. Likewise, defect #3 is determined with respect to section \textcircled{3}. However, in the case of section \textcircled{3}, the defective area is designated as extending to an end of the area containing the defect. Since a defect is not detected in section \textcircled{4}, a defective area is not determined in section \textcircled{4}.

Temporary defect information #1 is recorded when recording operation #1 is expected to end, and after the recording and verifying of data in the section \textcircled{4}, i.e., when a user presses the eject button of a recording apparatus or recording of user data allocated in a recording operation is completed. Temporary defect information #1 contains information regarding defects #1 through #3 occurring in sections \textcircled{1} through \textcircled{4}. Only an area containing a defect is determined to be a defective area in section \textcircled{4}, and an area from the area containing a defect to the following area containing data is determined to be the defective area in sections \textcircled{5} and \textcircled{6}. Similarly, temporary defect information #2 is recorded according to recording operation #2. Temporary defect information #1 also contains information regarding an area part in which user data is recorded according to recording operation #1, the part having a defect and thus being designated as a defective area. Also, temporary defect information #2 contains information regarding an area part in which the user data is recorded according to recording operation #2, the part having a defect and thus being designated as another defective area. Also, temporary defect information #2 further contains the information contained in temporary defect information #1.

When a defect is detected from an area of disc 100, data recording may be performed in one of two methods. In the first method, only the specified area is designated as a defective area, data recorded in the defective area is not rewritten, and data recording is continued after the defective area. In the second method, data recorded in the defective area, which includes an area from the area containing the defect to the following area containing data and which is designated a defective area, is rewritten. That is, the defective data is restored using slipping replacement, and then, the data recording is continued. Selection of one of the first and second methods is determined depending on the type of data to be recorded. For instance, if the data to be recorded is AV data that needs to be reproduced in real time, the first method is selected. That is, only the area containing the defect is designated as a defective area and data recorded in the defective area is not rewritten. In contrast, if the data to be recorded is control data, such as navigation data that is used to reproduce, search for, or edit the AV data, the second method is selected. In data reproduction, the degree of error due to control data loss is greater than that which is due to AV data loss.

According to embodiments of the invention, a reason to choose to rewrite data recorded in a defective area, based on data characteristics will now be described. In general, AV data needs to be reproduced in real time because AV data is perceived by human ears when AV data is reproduced. Human visual and auditory senses are more sensitive to an error in real-time reproduction of AV data than to an error in reproduction of specific AV data content caused by a trivial defect contained in the AV data. In fact, human ears are substantially incapable of detecting an error when audio data is incompletely reproduced. As specified previously, when an area of a disc is designated as a defective area, slipping replacement may be used to rewrite data to a following area. That is, when an area of a disc is designated as a defective area, the following area where data is recorded is also considered as unavailable and determined to be a defective area, and the data recorded in the defective area is rewritten. In this case, the defective area is skipped and data is read from the next area during reproduction of the data. However, skipping the defective area causes a delay in reading data from the disc, and the delay in reading makes reproduction of data in real-time difficult. As is described above, human ears are more sensitive to an error caused by a failure of real-time reproduction than an error caused by incomplete reproduction of AV data. In general, a disc drive included in a reproducing apparatus has various types of error correction functions such as error correction code (ECC). Thus, the disc drive may be capable of restoring at least a portion of data that cannot be appropriately read during the reproduction operation. For this reason, when a defect exists in an area of a disc during AV data recording, only the specified area is designated as the defective area and data recorded in the defective area is not rewritten in another area.

It is noted that a case exists where AV data is reproduced in real time but does not need to be recorded in real time. The case includes storing AV data in an auxiliary storage device, such as a hard disc drive (HDD), and recording the stored AV data on the disc 100. That is, AV data may be recorded using an editing tool to be used with AV data. In particular, AV data that does not need to be recorded in real time may be easily recorded according to the present invention.

In contrast, if only a portion of control data is lost, reproducing, editing, and searching for the control data may be difficult. Thus, if a defect exists in an area of a disc during the recording of control data, both the area having the defect and the following area containing data is designated as a defective area and data recorded in the defective area is rewritten in another area.

The diagram of FIG. 4 illustrates data recording. More specifically, the diagram of FIG. 4 illustrates a first recording operation on a disc where a defect exists, using one of two methods. In the first method, only the area having the defect is designated as a defective area and data recording is continued after the defective area without rewriting data previously recorded in the defective area. In the second method, a defective area is designated to include the area having the defect and the following area containing data. Following the designations the data previously recorded in the defective area is rewritten. However, the present invention is not limited to this description. That is, disc defects may be processed according to other methods besides the first and second methods, depending on a format of recorded data.

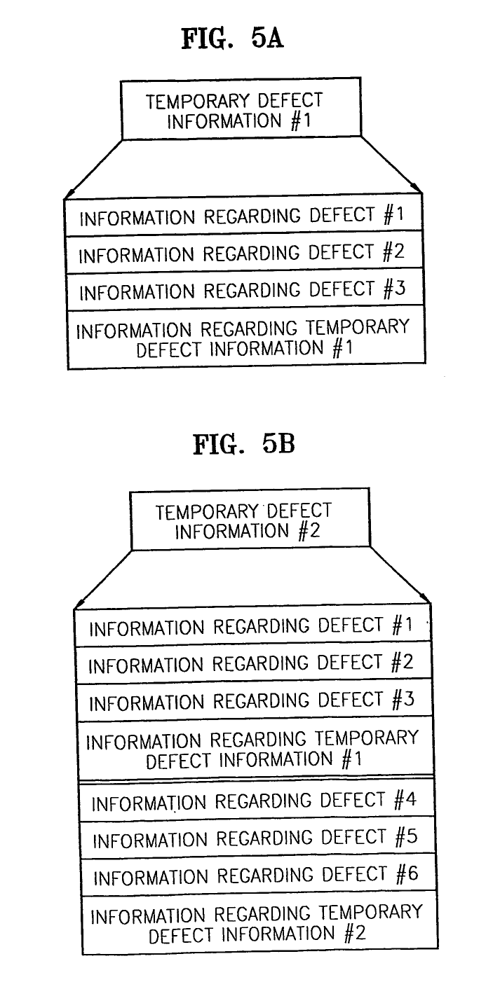

FIGS. 5A and 5B illustrate data structures of temporary defect information according to embodiments of the present invention. Referring to FIG. 5A, temporary defect information #1 contains information regarding defect #1, defect #2, and defect #3. The information regarding defect #1 discloses the position of defect #1 as recorded in the disc, the information regarding defect #2 discloses the position of defect #2 as recorded in the disc, and the information regarding defect #3 discloses the position of defect #3 as recorded in the disc.

Temporary defect information #1 also includes the information regarding defect #1, the information regarding defect #2, the information regarding defect #3, and the information regarding temporary defect information #1. The information regarding temporary defect information #1 indicates the position of temporary defect information #1. Reading the information recorded in temporary defect information #1 during reproduction of user data is not required since the user data is not recorded in temporary defect information #1. That is, for the reproduction of the user data, distinguishing between defective area #i and temporary defect information #1 is meaningless. Therefore, temporary defect information #1 contains position information and thus may be useful in that the information may be used to indicate that the user data is not recorded in temporary defect information #1 during the reproduction of the user data.

Referring to FIG. 5B, temporary defect information #2 includes all of the information contained in temporary defect information #1 and further contains information regarding defects #4, #5, and #6, in addition to the information recorded in temporary defect information #2. Temporary defect information #2 also contains information regarding the position of temporary defect information #1.

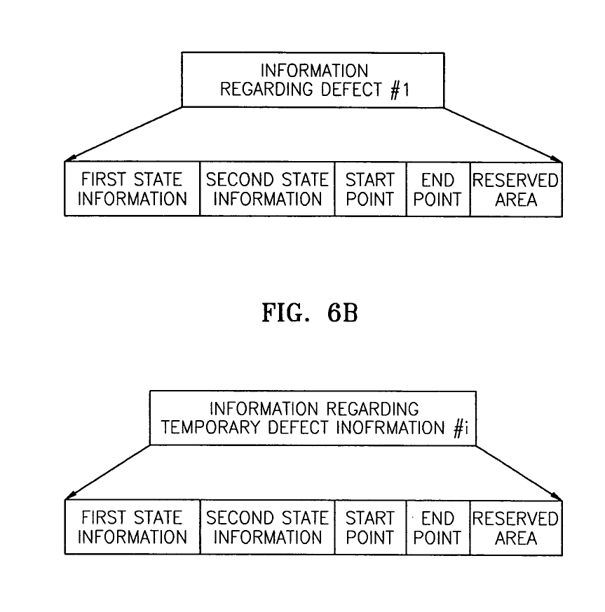

FIGS. 6A and 6B illustrate data structures of information regarding defect #i recorded in a temporary defect information area, and information regarding temporary defect information #i. Referring to FIG. 6A, the information regarding defect #i includes first state information, second state information, starting and ending points, and a reserved area of defect #i. State information is flag information that indicates whether the present area is a defective area in which a defect exists or is a temporary defect information area in which temporary defect information is recorded. In this embodiment, the first state information is included in the information regarding defect #i and thus must be understood as flag information indicating that the present area is a defective area. The second state information is flag information that indicates one of two options. The first option declares that only the area having the defect is designated as the defective area and that data recording is continued after the defective area without any rewriting of the data previously recorded in the defective area. The second option declares that an area from the area having the defect to the following area containing data is designated as a defective area. Following the designation the data recorded in the defective area is rewritten. In the case of defect area #1 shown in FIG. 4, which includes only the area having the defect, the second state information discloses designation of a defective area covering defect area #1 and data recorded in defect area #1 as not rewritten. The information regarding the starting point represents the start of the present area, i.e., the start of the defect #i. The information regarding the ending point represents the end of the present area, i.e., the end of the defect #i. The reserved area is referred to as an area that is reserved for recording other information.

Referring to FIG. 6B, the information regarding temporary defect information #i also includes first state information, second state information, starting and ending points, and a reserved area of temporary defect information #i. State information is flag information that indicates whether the present area is a defective area in which a defect exists or is an area in which temporary defect information is recorded. The first state information included in the information regarding temporary defect information #i is flag information indicating that a present area is an area in which temporary defect information is recorded, rather than an area in which a defect exists. The inclusion of the second state information into the information regarding temporary defect information #i is optional. The second state information is flag information indicating the same as that which is described for the information regarding defect #i. If the verify-after-write method is also performed on data recorded in a temporary defect information area and the data is rewritten when a defect exists in the temporary defect information area, the second state information is flag information indicating the rewriting of the data.

Hereinafter, a defect management method according to the present invention will be described.

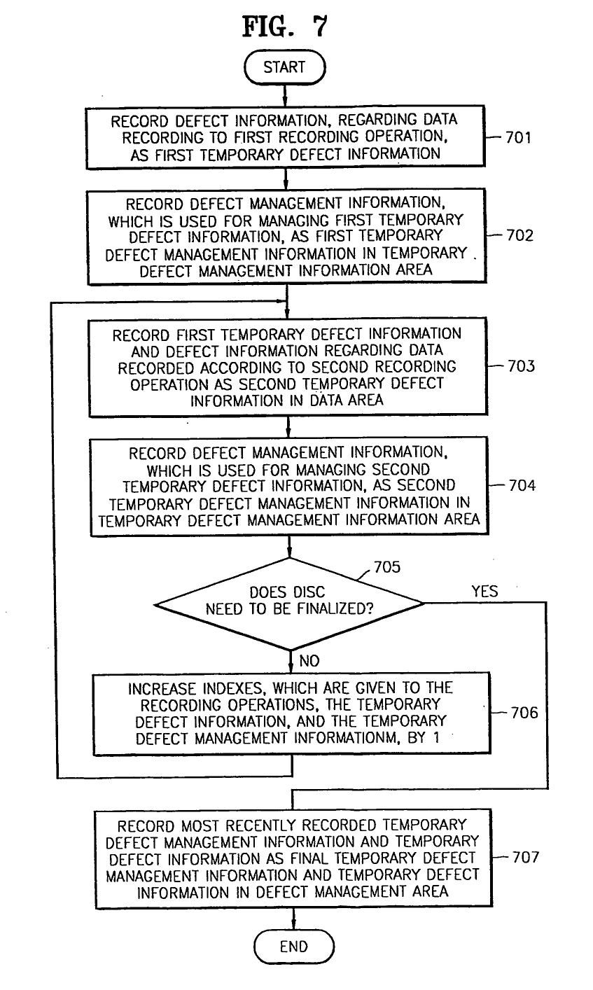

FIG. 7 is a flowchart illustrating a defect management method according to an embodiment of the present invention. Referring to FIG. 7, in operation 701, a recording apparatus records defect information, regarding data recorded according to a first recording operation, as first temporary defect information in a data area of a disc. This process serves to manage defects in the disc. In operation 702, the recording apparatus records defect management information, which is used to manage the first temporary defect information, as first temporary defect management information in a temporary defect management information area in at least one of a lead-in area and a lead-out area of the disc. In operation 703, the recording apparatus records the first temporary defect information and defect information, regarding data recorded according to a second recording operation, as second temporary defect information in the data area. In operation 704, the recording apparatus records defect management information, which is used to manage the second temporary defect information, as second temporary defect management information in the temporary defect management information area. In operation 705, whether the disc needs to be finalized is checked. In operation 706, if the disc does not need to be finalized according to the result of operation 705, operations 701 through 704 are repeated while indexes, which are given to the recording operations, the temporary defect information, and the temporary defect management information, are increased. In an embodiment of the invention, this increase is by a value of 1. During the finalizing of the disc, the most recent defect management information and temporary defect information, which are recorded until operation 704, are recorded in a DMA in operation 707. That is, the most recently recorded temporary defect management information and temporary defect information are recorded as the final temporary defect management information and temporary defect information in the DMA. In operation 707, the final temporary defect information and defect management information may be recorded repeatedly in the DMA to increase the reliability of data detection. Further, the verify-after-write method may be performed on the final temporary defect management information and temporary defect information. If a defect is detected from this information, the area of the disc in which the defect exists and data recorded after the area with the defect may be regarded as unavailable, i.e., they are designated as a defective area, and the final temporary defect management information and temporary defect information may be recorded again after the defective area.

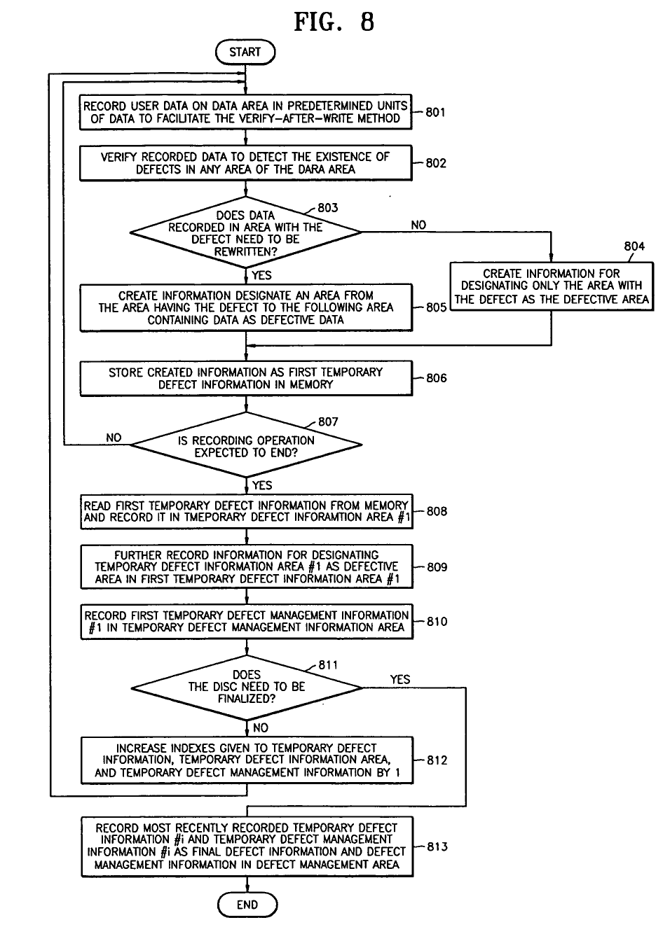

FIG. 8 is a flowchart illustrating a defect management method according to another embodiment of the present invention. Referring to FIG. 8, a recording apparatus records user data on a data area of a disc in predetermined units of data to facilitate the verify-after-write method, in operation 801. In operation 802, the data recorded in operation 801 is verified to detect the existence of detects in any area of the data area where a defect exists. In operation 803, whether data recorded in the area having the defect will be rewritten is determined. As mentioned above, the rewriting of data is determined in consideration of the characteristics of data to be recorded. In one option, only the area with a defect is designated as the defective area and data recorded in the defective area is not rewritten. In the other option, both the area with the defect and the following area containing data are designated as the defective area and data recorded in the defective area is rewritten.

If the data recorded in the area having the defect will not be rewritten according to the result of operation 803, defect information is created in operation 804 and used to designate only the area having the defect as the defective area. In contrast, if the data recorded in the area having the defect will be rewritten according to the result of operation 803, defect information is created in operation 805, and used to designate the area from the area having the defect to the following area containing data as the defective area. In operation 806, the defect information created in operation 804 or operation 805 is stored as first temporary defect information. In operation 807, whether a recording operation is expected to end is checked. If the recording operation is not likely to end according to the determination of operation 807, operations 801 through 806 are repeated before the end of the recording operation.

If the recording operation is likely to end, i.e., the recording of the user data is complete by user input or according to the recording operation, according to the determination in operation 807, the first temporary defect information is read and recorded in temporary defect information area #1 of the data area, in operation 808. In operation 809, information designating temporary defect information area #1 as a defective area is further recorded in first temporary defect information area #1. In operation 810, first temporary defect management information #1, which is used to manage temporary defect information #1, is recorded in a temporary defect management information area. In operation 811, whether the disc needs to be finalized is checked. If the disc is not to be finalized according to the result of operation 11, operations 801 through 810 are repeated before the finalizing. In operation 812, indexes, which are given to the temporary defect information, the temporary defect information area, and the temporary defect management information, are increased whenever operations 801 through 810 are repeated. According to an embodiment of the invention, the increase is by a value of 1. If the disc needs to be finalized, according to determination in operation 811, the most recently recorded temporary defect information #i and temporary defect management information #i are recorded as the final temporary defect information and temporary defect management information in a DMA in operation 813. The final defect information and defect management information may be recorded repeatedly in the DMA several times so as to increase the reliability of data detection. Further, the verify-after-write method may be performed on the final temporary defect management information and temporary defect information. If a defect is detected from this information, the area of the disc in which the defect exists and the following area containing data may be regarded as unavailable, i.e., the two areas are designated as a defective area, and the final temporary defect management information and temporary defect information may be again recorded after the defective area.

### INDUSTRIAL APPLICABILITY

As is described above, the present invention provides a disc defect management method that is applicable to write once discs and which is suitable to record different types of data so as to enable more appropriate real-time data reproduction of data. Further, according to the present invention, a temporary defect information area is allotted to the data area of a disc, which stores defect information without reducing the recording capacity of the disc. During the finalization of a disc, only the most recently recorded defect information is read from the temporary defect information area and recorded in a defect management area (DMA) so as to enable efficient use of the DMA whose recording capacity is limited. Meanwhile, recording user data on even a write once disc while performing defect management is possible. Thus, more stable backup operations may be performed without interruptions.

Although a few embodiments of the present invention have been shown and described, it would be appreciated by those skilled in the art that changes may be made in these embodiments without departing from the principles and spirit of the invention, the scope of which is defined in the claims and their equivalents.

1. A method of managing defects in a disc, comprising:
(a) recording data in predetermined units of data;
(b) verifying the recorded data to detect an area of the disc in which a defect exists;
(c) designating an area from the defective area to the following area containing data as a defective area or designating only the defective area as the defective area;
(d) recording information regarding the designated defective area as temporary defect information in a data area of the disc; and
(e) recording information, which is used to manage the temporary defect information, in a temporary defect management information area.

2. The method of claim 1, further comprising;
(f) repeating operations (a) through (e) before finalizing of the disc, wherein previously recorded information is recorded with the temporary defect information during the (d) operation; and
(g) recording information, which is most recently recorded in the temporary defect information area and the temporary defect management information area in a defect management area during the finalizing of the disc.

3. The method of claim 1, wherein during the (c) operation, the area from the area having the defect to the following area containing data is designated as a the defective area or only the area having the defect is designated as the defective area, depending on the type of the recorded data.

4. The method of claim 3, wherein during the (c) operation, only the defective area is designated as the defective area when the recorded data is AV data, and the area from the defective area to the following area containing data is designated as the defective area when the recorded data is control data.

5. A method of managing defects in a disc, comprising:
(a) recording data in predetermined units of data;
(b) verifying the recorded data to detect an area of the disc in which a defect exists;
(c) designating an area from the defective area to the following area containing data as a defective area as a defective area, or designating only the defective area as the defective area;
(d) storing information regarding the designated defective area as first temporary defect information in memory;
(e) repeating operations (a) through (d) before a recording operation is expected to end;
(f) reading the temporary defect information from the memory and recording the temporary defect information in a temporary defect information area of the data area so as to correspond to the recording operation, when the recording operation is expected to end; and
(g) recording information, which is used to manage the information recorded in the temporary defect information area in the (f) operation, in a temporary defect management information area.

6. The method of claim 5, wherein during the (f) operation, information to designate the temporary defect information area is further recorded in the temporary defect information area.

7. The method of claim 6, further comprising:
(h) repeating operations (a) through (e before finalizing of the disc, wherein previously recorded information is recorded with the temporary defect information during the (f) operation in the temporary defect information area; and
(i) recording information, which is most recently recorded in the temporary defect information area and the temporary defect management information area, in a defect management area.

8. The method of claim 5, wherein during the (c) operation, the area from the defective area to the following area containing data is designated as the defective area, or only the defective area is designated as the defective area, depending on the type of the recorded data.

9. The method of claim 8, wherein during the (c) operation, only the defective area is designated as a defective area when the recorded data is AV data, and the area from the defective area to the following area containing data is designated as the defective area when the recorded data is control data.

10. A recording apparatus comprising;
a recording/reading unit that records data on or reads data from a disc; and
a controller that verifies the data recorded on the disc using the recording/reading unit so as to detect an area of the disc in which a defect exists, designates an area from the defective area to the following area containing data as a defective area or designates only the defective area as the defective area, creates information regarding the designated defective area, provides the created information to the recording/reading unit, controls the recording/reading unit to record the created information as temporary defect information in a data area of the disc, creates management information for managing the temporary defect information, provides the management information to the recording/reading unit, and controls the recording/reading unit to record the management information in a temporary defect management area.

11. The recording apparatus of claim 10, wherein the controller controls the recording/reading unit to further record the previously recorded information with the information, and controls the recording/reading unit to record information, which is most recently recorded in the temporary defect information area and the temporary defect management information area in a defect management area during finalizing of the disc.

12. The recording apparatus of claim 10, wherein the controller designates the area from the defective area to the following area containing data as the defective area, or designates only the area having the defect as the defective area, depending on the type of the recorded data.

13. The recording apparatus of claim 12, wherein the controller designates only the area having the defect as the defective area when the recorded data is AV data, and designates the area from the area having the defect to the following area containing data as the defective area when the recorded data is control data.

14. A recording apparatus comprising:
memory;
a recording/reading unit that records data on a disc in predetermined units of data and reads the recorded data from the disc; and
a controller that verifies the data recorded on the disc using the recording/reading unit so as to defect an area of the disc in which a defect exists; designates an area from the defective area to the following area containing data as a defective area or designates only the defective area as the defective area; stores information regarding the designated defective area as first temporary defect information in the memory; repeats the verifying of the data, the designating of the defective area, and the storing of information regarding the designated defective area before a recording operation is expected to end; reads the temporary defect information from the memory when the recording operation is expected to end; provides the read temporary defect information to the recording/reading unit; controls the recording/reading unit to record the temporary defect information in a temporary defect information area of the data area in a manner corresponding to the recording operation; creates management information for managing the temporary defect information area; provides the management information to the recording/reading unit; and controls the recording/reading unit to record the management information in a temporary defect management information area.

15. The recording apparatus of claim 14, wherein the controller creates information for the temporary defect information area, provides the created information to the recording/reading unit, and controls the recording/reading unit to further record the created information in the temporary defect information area.

16. The recording apparatus of claim 14, wherein the controller controls the recording/reading unit to further record the previously recorded information with the information; reads information, which is most recently recorded in the temporary defect information area and the temporary defect management information area, during the finalizing of the disc; and controls the recording/reading unit to record the most recently recorded information in the defect management area again.

17. The recording apparatus of claim 14, wherein the controller designates the area from the defective area to the following area containing data as the defective area or designates only the defective area as the defective area, depending on the type of the recorded data.

18. The recording apparatus of claim 17, wherein the controller designates only the defective area as the defective area when the recorded data is AV data, and designates the area from the defective area to the following area containing data as the defective area when the recorded data is control data.

19. A disc having defect management structures, comprising:
a data area in which data and information regarding designated defective area are recorded,
wherein an area from the defective area to the following area containing data is designated as the defective area or only the defective area is designated as the defective area.

20. The disc of claim 19, wherein the area from the area having the defect to the following area containing data is designated as the defective area or only the area having the defect is designated as the defective area, depending on the type of the recorded data.

21. The disc of claim 20, wherein only the defective area is designated as the defective area when the recorded data is AV data, and the area from the defective area to the following area containing data is designated as the defective area when the recorded data is control data.
